(19) United States
(12) Patent Application Publication
(10) Pub. No.: US 2024/0055508 A1
(43) Pub. Date: Feb. 15, 2024

(54) SEMICONDUCTOR DEVICE AND METHOD FOR MANUFACTURING THE SAME

(71) Applicant: INNOSCIENCE (SUZHOU) SEMICONDUCTOR CO., LTD., Suzhou City (CN)

(72) Inventors: Jian RAO, Suzhou City (CN); Jheng-Sheng YOU, Suzhou City (CN); Weixing DU, Suzhou City (CN); Ming-Hong CHANG, Suzhou City (CN)

(21) Appl. No.: 17/635,002

(22) PCT Filed: Jan. 11, 2022
(86) PCT No.: PCT/CN2022/071191

§ 371 Date: Feb. 14, 2022

(51) Int. Cl. H01L 29/778; H01L 29/06; H01L 29/20; H01L 29/66

(52) U.S. Cl. CPC H01L 29/7786; H01L 29/0688; H01L 29/2003; H01L 29/66462

(57) ABSTRACT

A nitride-based semiconductor device includes a first nitride-based semiconductor layer, a second nitride-based semiconductor layer, a doped nitride-based semiconductor layer, a gate electrode, and a protection layer. The doped nitride-based semiconductor layer has a first portion and a second portion over the first portion and narrower than the first portion. The gate electrode is disposed over the doped nitride-based semiconductor layer and narrower than the first portion. The protection layer is disposed over the doped nitride-based semiconductor layer and the gate electrode. A top surface of the first portion of the doped nitride-based semiconductor layer is covered by the protection layer, and a sidewall of the first portion of the doped nitride-based semiconductor layer is free from coverage by the protection layer.

### FIELD OF THE DISCLOSURE

The present disclosure generally relates to a nitride-based semiconductor device. More specifically, the present disclosure relates to a nitride-based semiconductor device having a doped nitride-based semiconductor layer having portions with different thicknesses.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

With respect to the nitride-based devices, how to reduce/alleviate the breakdown phenomenon induced by a strong peak electric field near a gate edge has become an important issue. When the device is operated under a high voltage condition, the breakdown phenomenon easily occurs, thereby deteriorating the electrical properties and the reliability. Thus, the applications of the nitride-based devices are limited.

### SUMMARY OF THE DISCLOSURE

In accordance with one aspect of the present disclosure, a semiconductor device is provided. A nitride-based semiconductor device includes a first nitride-based semiconductor layer, a second nitride-based semiconductor layer, a doped nitride-based semiconductor layer, a gate electrode, and a protection layer. The second nitride-based semiconductor layer is disposed on the first nitride-based semiconductor layer, and has a bandgap higher than a bandgap of the first nitride-based semiconductor layer. The doped nitride-based semiconductor layer is disposed over the second nitride-based semiconductor layer. The doped nitride-based semiconductor layer has a first portion and a second portion over the first portion and narrower than the first portion. The gate electrode is disposed over the doped nitride-based semiconductor layer and narrower than the first portion. The protection layer is disposed over the doped nitride-based semiconductor layer and the gate electrode. A top surface of the first portion of the doped nitride-based semiconductor layer is covered by the protection layer, and a sidewall of the first portion of the doped nitride-based semiconductor layer is free from coverage by the protection layer.

In accordance with one aspect of the present disclosure, a semiconductor device is provided. A nitride-based semiconductor device includes a first nitride-based semiconductor layer, a second nitride-based semiconductor layer, a doped nitride-based semiconductor layer, a gate electrode, a source electrode, and a drain electrode. The second nitride-based semiconductor layer is disposed on the first nitride-based semiconductor layer, and has a bandgap higher than a bandgap of the first nitride-based semiconductor layer. The doped nitride-based semiconductor layer is disposed over the second nitride-based semiconductor layer. The gate electrode is disposed over the doped nitride-based semiconductor layer and narrower than the doped nitride-based semiconductor layer. The source electrode and the drain electrode are disposed over the second nitride-based semiconductor layer. A distance from the source electrode to the doped nitride-based semiconductor layer is less than a distance from the drain electrode to the doped nitride-based semiconductor layer.

In accordance with one aspect of the present disclosure, a method for manufacturing a semiconductor device is provided. The method includes steps as follows. A first nitride-based semiconductor layer is formed to be disposed over a substrate. A second nitride-based semiconductor layer is formed on the first nitride-based semiconductor layer. A doped nitride-based semiconductor layer is formed over the second nitride-based semiconductor layer. A gate electrode is formed on the doped nitride-based semiconductor layer with portions of the doped nitride-based semiconductor layer exposed from the gate electrode. The exposed portion of the doped nitride-based semiconductor layer is thinned. A protection layer is formed to cover the doped nitride-based semiconductor layer and the gate electrode. Portions of the protection layer are removed to exposed the doped nitride-based semiconductor layer. Portions of the doped nitride-based semiconductor layer which are exposed from the protection layer are removed.

By the above configuration, in embodiments of the present disclosure, the doped nitride-based semiconductor layer is formed to have portions with different thicknesses, such that the 2DEG concentration distribution can be changed, thereby achieving an uniform electrical distribution. Also, the breakdown voltage of the semiconductor device can be enhanced.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a top view of a semiconductor device according to some embodiments of the present disclosure;

FIG. 1B is a vertical cross-sectional view of the semiconductor device along the line 1B-1B′ in the FIG. 1A;

FIG. 2A, FIG. 2B, FIG. 2C, FIG. 2D, and FIG. 2E show different stages of a method for manufacturing a nitride-based semiconductor device according to some embodiments of the present disclosure;

FIG. 3 is a vertical cross-sectional view of a semiconductor device according to some embodiment of the present disclosure;

FIG. 4 is a top view of a semiconductor device according to some embodiment of the present disclosure;

FIG. 5 is a top view of a semiconductor device according to some embodiment of the present disclosure;

FIG. 6 is a top view of a semiconductor device according to some embodiment of the present disclosure;

FIG. 7 is a top view of a semiconductor device according to some embodiment of the present disclosure;

FIG. 8 is a vertical cross-sectional view of a semiconductor device according to some embodiment of the present disclosure;

FIG. 9 is a vertical cross-sectional view of a semiconductor device according to some embodiment of the present disclosure;

FIG. 10 is a vertical cross-sectional view of a semiconductor device according to some embodiment of the present disclosure; and

FIG. 11 is a vertical cross-sectional view of a semiconductor device according to some embodiment of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

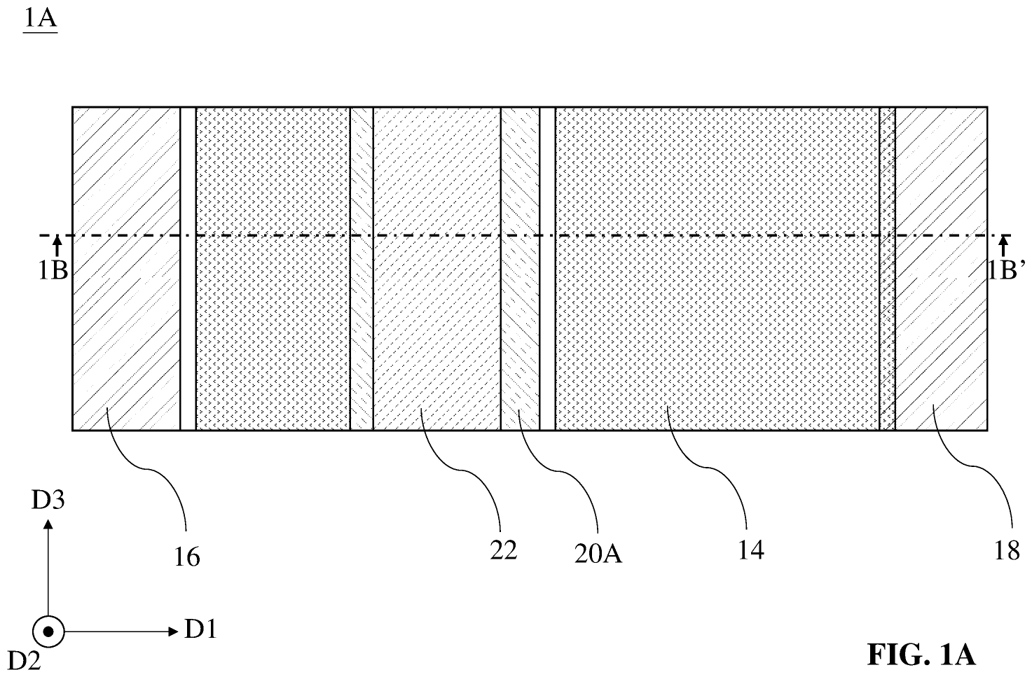

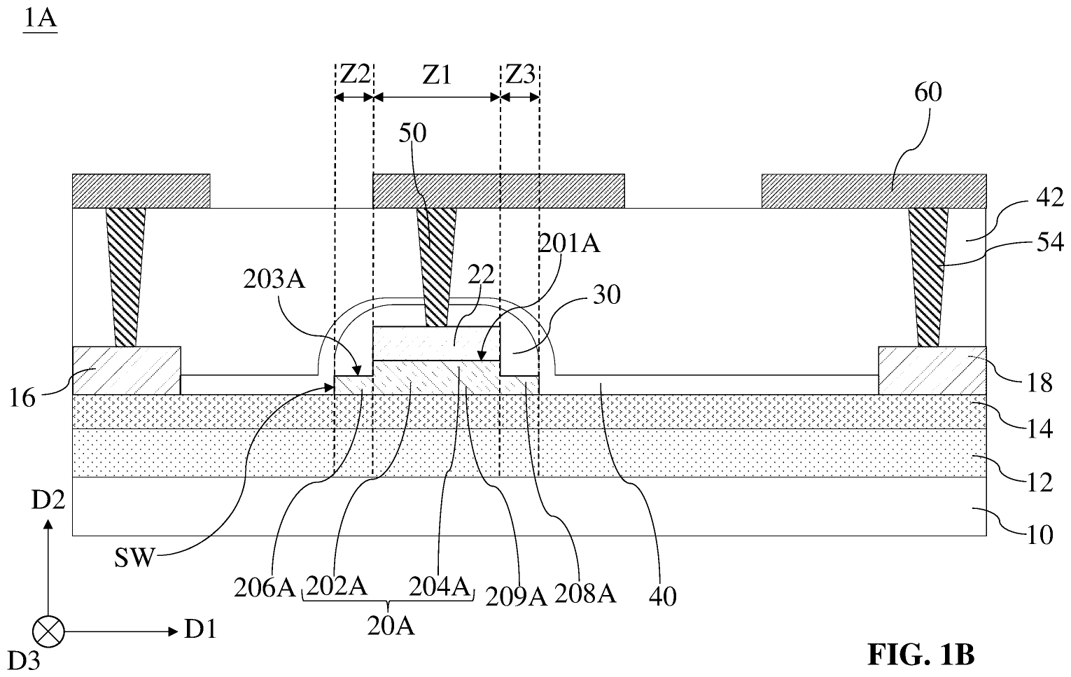

FIG. 1A is a top view of a semiconductor device 1A according to some embodiments of the present disclosure. FIG. 1B is a vertical cross-sectional view of the semiconductor device 1A along the line 1B-1B′ in the FIG. 1A. The directions D1, D2 and D3 are labeled in the FIGS. 1A and 1B, in which the directions D1, D2 and D3 are different from each other. The directions D1 to D3 are perpendicular to each other.

The semiconductor device 1A includes a substrate 10, nitride-based semiconductor layers 12, 14, electrodes 16, 18, a doped nitride-based layer 20A, a gate electrode 22, a protection layer 30, a dielectric layer 40, a passivation layer 42, a plurality of contact vias 50 and 54, and a circuit layer 60.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

A buffer layer (not shown) can be disposed on/over/above the substrate 10. The buffer layer can be disposed between the substrate 10 and the nitride-based semiconductor layer 12. The buffer layer can be configured to reduce lattice and thermal mismatches between the substrate 10 and the nitride-based semiconductor layer 12, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer. The nucleation layer can be configured to provide a transition to accommodate a mismatch/difference between the substrate 10 and a III-nitride layer of the buffer layer. The exemplary material of the nucleation layer can include, for example but is not limited to AlN or any of its alloys.

The nitride-based semiconductor layer 12 can be disposed on/over/above the substrate 10. The nitride-based semiconductor layer 14 can be disposed on/over/above the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, AlₓGa₍₁₋ₓ₎N, where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N, where y≤1.

The exemplary materials of the nitride-based semiconductor layers 12 and 14 are selected such that the nitride-based semiconductor layer 14 has a bandgap (i.e., forbidden band width) greater/higher than a bandgap of the nitride-based semiconductor layer 12, which causes electron affinities thereof different from each other and forms a heterojunction therebetween. For example, when the nitride-based semiconductor layer 14 is an AlGaN layer having bandgap of approximately 4.0 eV, the nitride-based semiconductor layer 12 can be selected as an undoped GaN layer having a bandgap of approximately 3.4 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The electrodes 16 and 18 can be disposed on/over/above the nitride-based semiconductor layer 14. The electrodes 16 and 18 are directly in contact with the nitride-based semiconductor layer 14. Referring to the FIG. 1A, the electrodes 16 and 18 can extend along the direction D3, such that each of the electrodes 16 and 18 can have a strip profile. In some embodiments, the electrode 16 can serve as a source electrode. In some embodiments, the electrode 16 can serve as a drain electrode. In some embodiments, the electrode 18 can serve as a source electrode. In some embodiments, the electrode 18 can serve as a drain electrode. The role of the electrodes 16 and 18 depends on the device design.

In some embodiments, the electrodes 16 and 18 can include, for example but are not limited to, metals, alloys, doped semiconductor materials (such as doped crystalline silicon), compounds such as silicides and nitrides, other conductor materials, or combinations thereof. The exemplary materials of the electrodes 16 and 18 can include, for example but are not limited to, Ti, AlSi, TiN, or combinations thereof.

Each of the electrodes 16 and 18 may be a single layer, or plural layers of the same or different composition. The electrodes 16 and 18 form ohmic contacts with the nitride-based semiconductor layer 14. Furthermore, the ohmic contacts can be achieved by applying Ti, Al, or other suitable materials to the electrodes 16 and 18. In some embodiments, each of the electrodes 16 and 18 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

In order to avoid the breakdown phenomenon induced by strong peak electric field near the gate edge which limits the device performance, one approach to lower the peak of the electric field is to utilize multiple field plates to split the electric field into more peaks so as to achieve a more uniform electric field distribution. However, such a configuration would encounter the yield rate and the reliability issues due to complexity of the manufacturing process thereof. Besides, excessive field plates may induce unwanted parasitic/stray capacitances which limits the maximum operating frequency of the device.

At least to avoid the afore-mentioned issues, the present disclosure is to provide a novel structure for the nitride-based semiconductor devices.

The doped nitride-based semiconductor layer 20A can be disposed on/over/above the nitride-based semiconductor layer 14. The doped nitride-based semiconductor layer 20A is in contact with the nitride-based semiconductor layer 14. The gate electrode 22 is disposed on/over/above a top portion 204A of the doped nitride-based semiconductor layer 20A and the nitride-based semiconductor layer 14.

Each of the doped nitride-based semiconductor layer 20A and the gate electrode 22 extends along the direction D3 to have a strip profile (see FIG. 1A). A distance from the electrode 16 to the doped nitride-based semiconductor layer 20A is less than a distance from the electrode 18 to the doped nitride-based semiconductor layer 20A.

The doped nitride-based semiconductor layer 20A further has a bottom portion 202A connected to the top portion 204A. The top portion 204A is on/over/above the bottom portion 202. The top portion 204A is narrower than the bottom portion 202A. The gate electrode 22 is in contact with the top portion 204A of the doped nitride-based semiconductor layer 20A. The gate electrode 22 is confined in the boundary of the top portion 204A of the doped nitride-based semiconductor layer 20A. The gate electrode 22 has a width substantially the same as a width of the top portion 204A of the doped nitride-based semiconductor layer 20A.

The doped nitride-based semiconductor layer 20A includes top surfaces 201A and 203A, in which the top surface 203A is in a position lower than the top surface 201A. The top portion 204A has the top surface 201A, and the bottom portion 202A has the top surface 203A. The top surface 201A is in contact with the gate electrode 22.

To be more specific, the bottom portion 202A further has two extending portions 206A and 208A, and a middle portion 209A. The middle portion 209A is between the two extending portions 206A and 208A. The extending portions 206A and 208A extends from the middle portion 209A. The extending portions 206A and 208A protrude out of two opposite edges of the gate electrode 22/top portion 204A. In some embodiments, the width of the extending portion 206A is substantially the same as that of the extending portion 208A. Therefore, the total thicknesses of the middle portion 209A and the top portion 204A is greater than that of the extending portion 206A/208A. From another point of view, the doped nitride-based semiconductor layer 20A can have different portions with different thicknesses.

The doped nitride-based semiconductor layer 20A can be a p-type doped III-V semiconductor layer. The exemplary materials of the doped nitride-based semiconductor layer 20A can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Zn, Cd, and Mg. In some embodiments, the nitride-based semiconductor layer 14 includes undoped GaN and the nitride-based semiconductor layer 12 includes AlGaN, and the doped nitride-based semiconductor layer 20A is a p-type GaN layer which can bend the underlying band structure upwards and to deplete the corresponding zone of the 2DEG region, so as to place the semiconductor device 1A into an off-state condition.

The exemplary materials of the gate electrode 22 may include metals or metal compounds. The gate electrode 22 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

In the exemplary illustration of FIG. 1B, the semiconductor device 1A is an enhancement mode device, which is in a normally-off state when the gate electrode 22 is at approximately zero bias. Specifically, the doped nitride-based semiconductor layer 20A may create at least one p-n junction with the nitride-based semiconductor layer 14 to deplete the 2DEG region, such that at least one zone of the 2DEG region corresponding to a position below the corresponding the gate electrode 22 has different characteristics (e.g., different electron concentrations) than the remaining portion of the 2DEG region and thus is blocked.

Due to such mechanism, the semiconductor device 1A has a normally-off characteristic. In other words, when no voltage is applied to the gate electrode 22 or a voltage applied to the gate electrode 22 is less than a threshold voltage (i.e., a minimum voltage required to form an inversion layer below the gate electrode 22), the zone of the 2DEG region below the gate electrode 22 is kept blocked, and thus no current flows therethrough.

In this regard, with respect to the doped nitride-based semiconductor layer 20A, since the thickness thereof is correlated with the quantity of p-type impurities stored in the p-type doped nitride-based semiconductor layer 20A, portions of the p-type doped nitride-based semiconductor layer 20A with different thicknesses can achieve depletion in different degrees for the 2DEG region. It can improve the reliability of devices.

To clearly state the configuration, zones Z1, Z2, and Z3 are labeled in FIG. 1B. The zone Z1 of the nitride-based semiconductor layer 14 is beneath the top portion 204A and the middle portion 209A; the zone Z2 of the nitride-based semiconductor layer 14 is beneath the extending portion 206A; the zone Z3 of the nitride-based semiconductor layer 14 is beneath the extending portion 208A. The zone Z1 is located between the zones Z2 and Z3.

Since the thickness of the top portion 204A in combination with the middle portion 209A is greater than the thicknesses of the extending portions 206A and 208A, the top portion 204 and the middle portion 209 can deplete electrons in the zone Z1 more than the zone Z2 or Z3. That is, the number of the electrons in the zone Z1 of the nitride-based semiconductor layer 14 depleted by the top portion 204A and the middle portion 209A is more than the number of the electrons in the zone Z2 of the nitride-based semiconductor layer 14 depleted by the extending portion 206A. Similarly, the top portion 204A and the middle portion 209A can deplete electrons in the zone Z1 more than electrons in a zone Z3 of the nitride-based semiconductor layer 14 depleted by the extending portion 206A.

In the exemplary illustration of FIG. 1B, the 2DEG concentration of the zone Z1 approaches to zero but greater than zero, meaning undepleted electrons still exist in the zone Z1. In other embodiments, the 2DEG concentration of the zone Z1 is about zero or exact zero, so electrons in the zone Z1 are almost depleted. The 2DEG concentration in the zone Z1 is not sufficient to make the device to be conducted.

As afore-described, the semiconductor device 1A has the normally-off characteristic. With respect to the configuration of the extending portions 206A and 208A, the 2DEG concentrations in zones Z2 and Z3 can be modulated, such that the extending portions 206A and 208A can reduce extent of change/variation of the 2DEG concentrations near the gate electrode 22 in the nitride-based semiconductor layer 14, thereby reducing/alleviating the breakdown phenomenon. The reliability of the semiconductor device 1A can be improved accordingly. That is, once change/variation in a 2DEG concentration is too sharp, breakdown phenomenon might be raised.

The protection layer 30 is disposed on/over/above the doped nitride-based semiconductor layer 20A and the gate electrode 22. The protection layer 30 covers the gate electrode 22 and the doped nitride-based semiconductor layer 20A. The protection layer 30 has a curved top surface. An entirety of the protection layer 30 is at a position higher than the top surface 203A of the bottom portion 202A of the doped nitride-based semiconductor layer 20A. The top surface 203A of the bottom portion 202A of the doped nitride-based semiconductor layer 20A is covered by the protection layer 30. A sidewall SW of the bottom portion 202A of the doped nitride-based semiconductor layer 20A is free from coverage by the protection layer 30. The sidewalls SW of the bottom portion 202A are vertical with respect to the nitride-based semiconductor layer 14.

The dielectric layer 40 is disposed on/over/above the nitride-based semiconductor layer 14, the protection layer 30, the doped nitride-based semiconductor layer 20A, and the gate electrode 22. Each of the electrodes 16 and 18 penetrate the dielectric layer 40 to make a contact with the nitride-based semiconductor layer 14.

The passivation layer 42 is disposed on/over/above the protection layer 40, and the electrodes 16, 18. Moreover, the passivation layer 42 can serve as a planarization layer which has a level top surface to support other layers/elements. In some embodiments, the passivation layer 42 can be formed as a thicker layer, and a planarization process, such as chemical mechanical polish (CMP) process, is performed on the passivation layer 42 to remove the excess portions, thereby forming a level top surface.

The material of the protection layer 30, the dielectric layer 40 and the passivation layer 42 can include, for example but are not limited to, dielectric materials. For example, each of the protection layer 30, the dielectric layer 40 and the passivation layer 42 can include, for example but are not limited to, SiNₓ, SiOₓ, Si₃N₄, SiON, SiC, SiBN, SiCBN, oxides, nitrides, plasma enhanced oxide (PEOX), or combinations thereof. In some embodiments, each of the protection layer 30, the dielectric layer 40 and the passivation layer 42 can be a multi-layered structure, such as a composite dielectric layer of Al₂O₃/SiN, Al₂O₃/SiO₂, AlN/SiN, AlN/SiO₂, or combinations thereof.

The contact via 50 is disposed within the protection layers 30, 40 and 42. The contact via 50 can penetrate the protection layers 30, 40 and 42. The contact via 50 can extend longitudinally to connect to the gate electrode 22. The contact vias 54 are disposed within the passivation layer 42. The contact vias 54 can penetrate the passivation layer 42. The contact vias 54 can extend longitudinally to connect to the electrodes 16 and 18, respectively. The upper surfaces of the contact vias 50, 54 are free from coverage of the passivation layer 42. The exemplary materials of the contact vias 50, 54 can include, for example but are not limited to, conductive materials, such as metals or alloys.

The circuit layer 60 can be disposed on/over/above the conductive vias 50 and 54, and the passivation layer 42. The circuit layer 60 can be in contact with the conductive vias 50 and 54, and the passivation layer 42. The circuit layer 60 may have metal lines, pads, traces, or combinations thereof, such that the circuit layer 60 can form at least one circuit. The circuit layer 60 can be connected with the electrodes 16 and 18 by the contact vias 54. The circuit layer 60 can be connected with the gate electrode 22 by the contact via 50. An external electronic device can send at least one electronic signal to the semiconductor device 1A by the circuit layer 60, and vice versa.

The exemplary materials of the circuit layer 60 can include, for example but are not limited to, conductive materials. The circuit layer 60 may include a single film or multilayered film having Ag, Al, Cu, Mo, Ni, Ti, alloys thereof, oxides thereof, nitrides thereof, or combinations thereof.

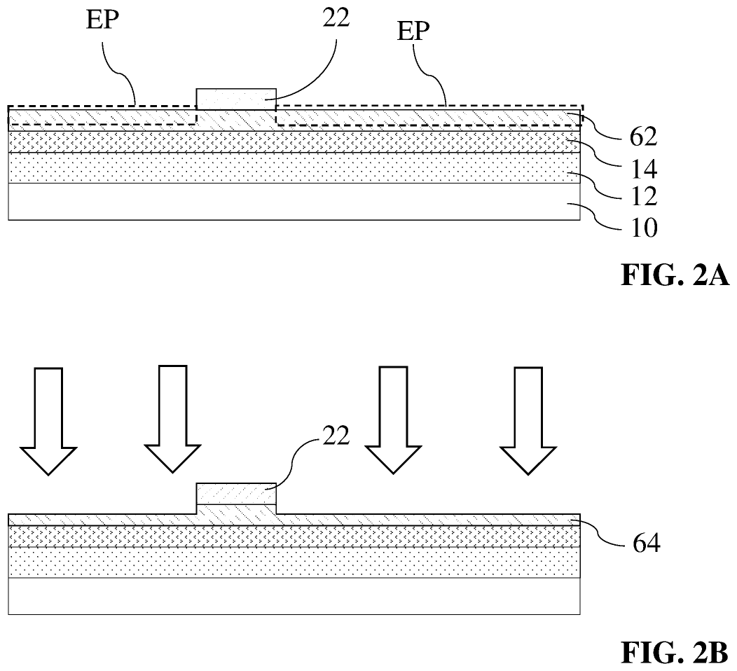

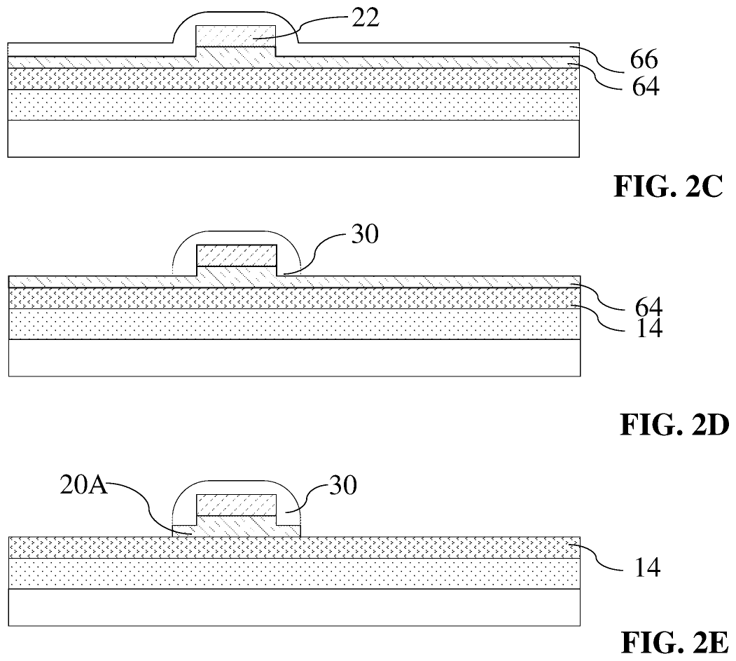

Different stages of a method for manufacturing the semiconductor device 1A are shown in FIG. 2A, FIG. 2B, FIG. 2C, FIG. 2D, and FIG. 2E, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a nitride-based semiconductor layer 12 is formed on/over/above a substrate 10 by using deposition techniques. A nitride-based semiconductor layer 14 is formed on/over/above the nitride-based semiconductor layer 12 by using deposition techniques, so that a heterojunction is formed therebetween. A blanket doped nitride-based semiconductor layer 62 can be formed on the nitride-based semiconductor layer 14. A gate electrode 22 can be formed on the blanket doped nitride-based semiconductor layer 62, and a portion EP of the blanket doped nitride-based semiconductor layer 62 are exposed from the gate electrode 22.

The formation of the gate electrode 22 includes deposition techniques and a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 2B, the exposed portion EP of the blanket doped nitride-based semiconductor layer 62 are thinned to form an intermediate doped nitride-based semiconductor layer 64. In some embodiments, an etching process is performed during the thinning step. During the etching process, the gate electrode 22 serves as a mask.

Referring to FIG. 2C, a blanket protection layer 66 is formed to cover the intermediate doped nitride-based semiconductor layer 64 and the gate electrode 22.

Referring to FIG. 2D, portions of the blanket protection layer 66 are removed to expose the intermediate doped nitride-based semiconductor layer 64, and thus a protection layer 30 is formed.

Referring to FIG. 2E, portions of the intermediate doped nitride-based semiconductor layer 64, which are exposed from the protection layer 30, are removed, and thus a doped nitride-based semiconductor layer 20A is formed. It should be noted that the blanket protection layer 66 is patterned into a profile viewed along a direction normal to the nitride-based semiconductor layer 14 during the patterning process in the FIG. 2D. The step of removing portions of the intermediate doped nitride-based semiconductor layer 64 is performed such that the same profile of the protection layer 30 is transferred to the doped nitride-based semiconductor layer 20A during the patterning process in the FIG. 2E.

Thereafter, the dielectric layer 40, the electrodes 16, 18, the passivation layer 42, the conductive vias 50, 54 and the circuit layer 60 can be formed, obtaining the configuration of the semiconductor device 1A as shown in FIGS. 1A and 1B.

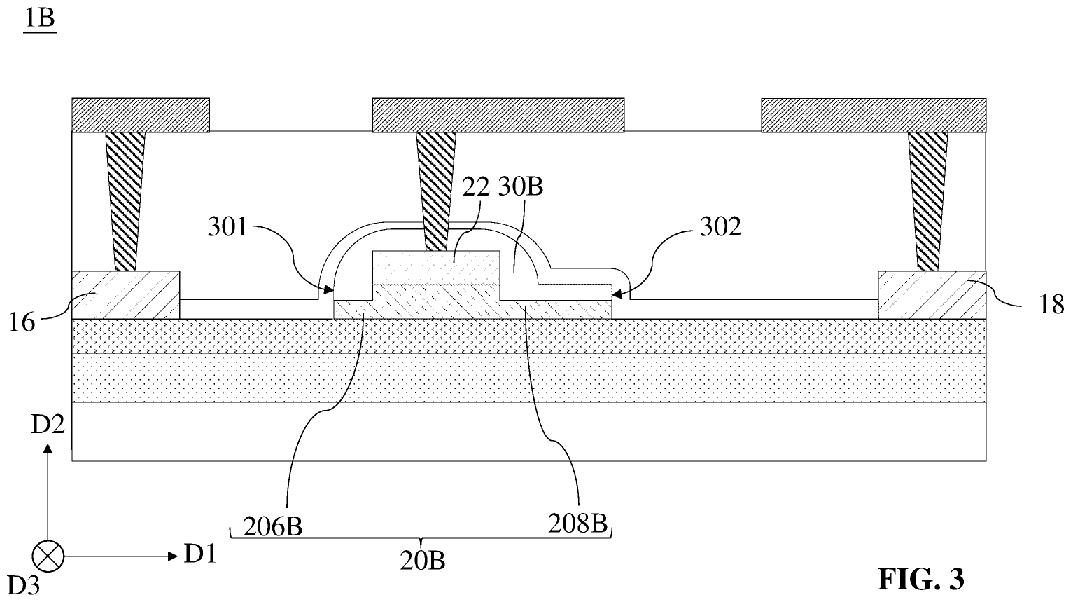

FIG. 3 is a vertical cross-sectional view of a semiconductor device according to some embodiment of the present disclosure. The semiconductor device 1B is similar to the semiconductor device 1A as described and illustrated with reference to FIGS. 1A and 1B, except that the doped nitride-based semiconductor layer 20A is replaced by a doped nitride-based semiconductor layer 20B; and the protection layer 30A is replaced by a protection layer 30B.

Specifically, the doped nitride-based semiconductor layer 20A includes extending portions 206B, 208B. The extending portion 206B is shorter than the extending portion 208B. That is to say, the profiles of the extending portions 206B and 208B viewed along the direction D3 are asymmetrical. On the other hand, the protection layer 30B has two opposite sidewalls 301, 302. The sidewall 301 is closer to the gate electrode 22 than the sidewall 302.

In the exemplary illustration of the present embodiment, the longer extending portion 208B is disposed between a larger region between the gate electrode 22 and the electrode 18, and the shorter extending portion 206B is disposed between a short region between the gate electrode 22 and the electrode 16. Such a length design can be further adapted to the configuration of the gate electrode 22 and the electrodes 16,18, so as to achieve a better electrical distribution. For example, the length design can be applied into a high voltage device. In the high voltage device, gate-drain side needs depletion stronger than gate-source side.

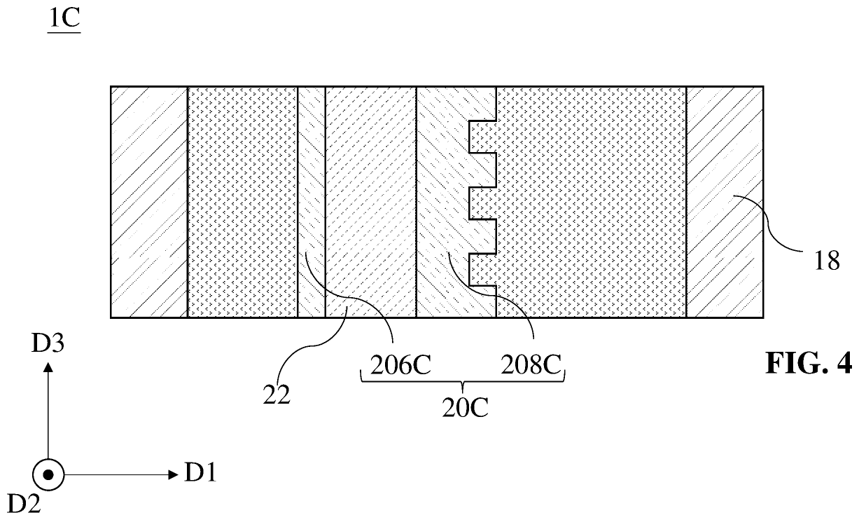

FIG. 4 is a top view of a semiconductor device 1C according to some embodiment of the present disclosure. The semiconductor device 1C is similar to the semiconductor device 1A as described and illustrated with reference to FIGS. 1A and 1B, except that the extending portions 206A and 208A can be replaced by the extending portions 206C and 208C, respectively.

The extending portion 206C viewed along a direction D2 normal to the nitride-based semiconductor layer 14 is in a rectangular profile. The extending portion 208C viewed along the direction D2 normal to the nitride-based semiconductor layer 14 is in a zig zag profile. The profiles of the extending portions 206C and 208C viewed along the direction D2 are asymmetrical. The extending portions 206C and 208C viewed along the direction D2 have different areas. Specifically, the area of the extending portion 206C viewed along the direction D2 is less than the area of the extending portion 208C viewed along the direction D2.

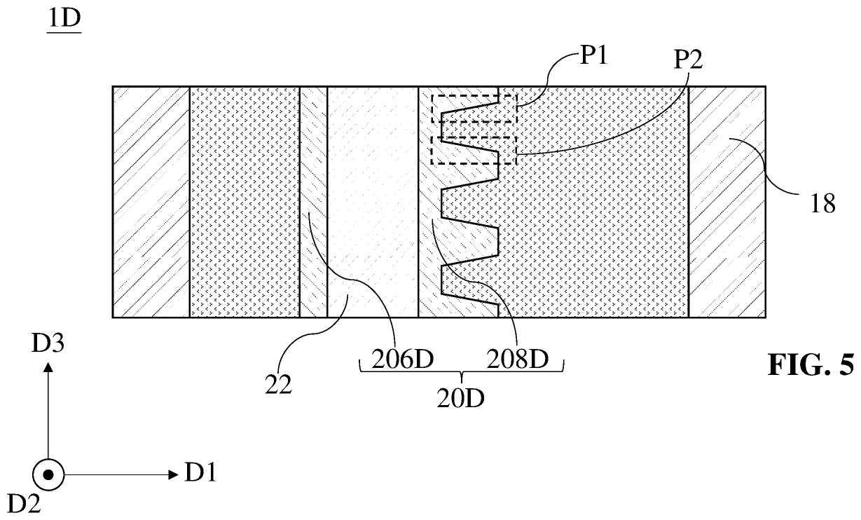

FIG. 5 is a top view of a semiconductor device 1D according to some embodiment of the present disclosure. The semiconductor device 1D is similar to the semiconductor device 1C as described and illustrated with reference to FIG. 4, except that the extending portion 208C is replaced by the extending portion 208D. The extending portion 208D viewed along the direction D2 has at least one taper profile. The distance from the electrode 18 to at least a portion of the extending portion 208D varies. For example, the distance from the electrode 18 to a portion P1 of the extending portion 208D increases, and the distance from the electrode 18 to another portion P2 of the extending portion 208D decreases.

In the embodiments of the semiconductor devices 1C and 1D, by designing different profiles of the extending portion 208C of the doped nitride-based semiconductor layer 20C and the extending portion 208D of the doped nitride-based semiconductor layer 20D, the 2DEG concentration distribution in a region between the gate electrode 22 and the electrode 18 can be further modulated, so as to satisfy different electrical properties requirements.

The profile of the extending portion 208C/208D above is made for modulation of the electrical distribution at the gate-drain side. For example, the zig zag profile as shown in FIG. 4 has periodical concaves such that the carrier flows can be collected in a desired path during on state. For example, the taper profile as shown in FIG. 5 has periodical concaves such that the carrier flows can be collected in a desired path during on state. The distribution of the carrier flows is related to the reliability of the semiconductor device. In a high voltage device, an unexpected electrical affect may result in device failure. Therefore, such the design can improve the performance of the semiconductor device, resulting from the control of the carrier flows in the desired paths.

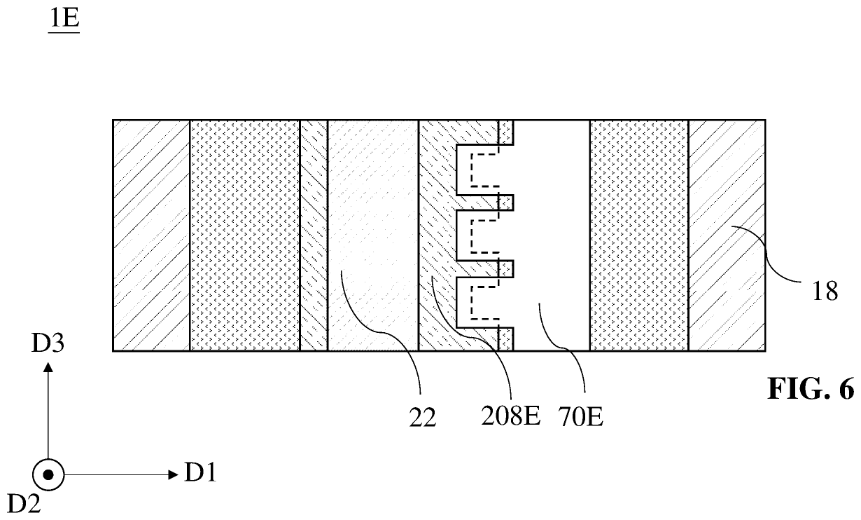

FIG. 6 is a top view of a semiconductor device 1E according to some embodiment of the present disclosure. The semiconductor device 1E is similar to the semiconductor device 1C as described and illustrated with reference to FIG. 4, except that the semiconductor device 1E further includes a field plate 70E. The field plate 70E is located between the gate electrode 22 and the electrode 18. The left sidewall of the field plate 70E near the extending portion 208E viewed along the direction D2 is in a zig zag profile. The right sidewall of the extending portion 208E viewed along the direction D2 is also in a zig zag profile. The profile of the left sidewall of the field plate 70E is complementary to the profile of the right sidewall of the extending portion 208E.

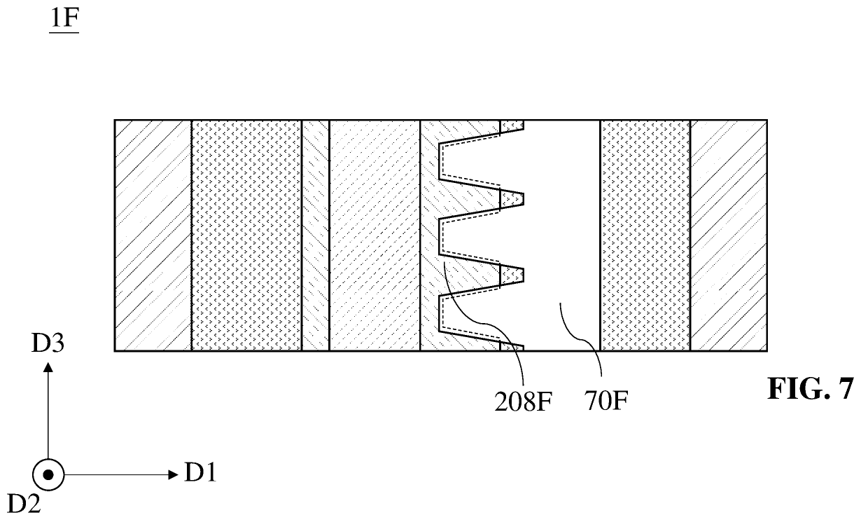

FIG. 7 is a top view of a semiconductor device 1F according to some embodiment of the present disclosure. The semiconductor device 1F is similar to the semiconductor device 1D as described and illustrated with reference to FIG. 5, except that the semiconductor device 1F further includes a field plate 70F. The left sidewall of the field plate 70F viewed along the direction D2 has at least one taper profile. The profile of the left sidewall of the field plate 70F is complementary to the profile of the right sidewall of the extending portion 208F.

In the embodiments of the semiconductor devices 1E and 1F, since the profile of the right sidewall of the extending portion 208E/208F is complementary to the profile of the left sidewall of the field plate 70E/70F, the extending portion 208E/208F can collaboratively modulate the electrical field distribution therein, so as to achieve a more uniform electrical field distribution. Therefore, in the embodiments of the present disclosure, the semiconductor devices 1E and 1F can still have uniform electric field distribution under a condition of using fewer field plates.

The field plate 70E/70F can modulate the electric field distribution where the carrier flows are concentrated in the 2DEG region, thereby avoid occurrence of breakdown voltage. Some portions of the right sidewall of the extending portion 208E/208F are free from the coverage of the field plate 70E/70F. In this regard, a field plate having a large area may raise a parasitic capacitance issue or a stress accumulation issue. Accordingly, the field plate 70E/70F is extended at the corresponding position (e.g., being overlapped with the concave of the zig zag profile of the extending portion 208E, thereby avoid the field plate 70E/70F having the over large area.

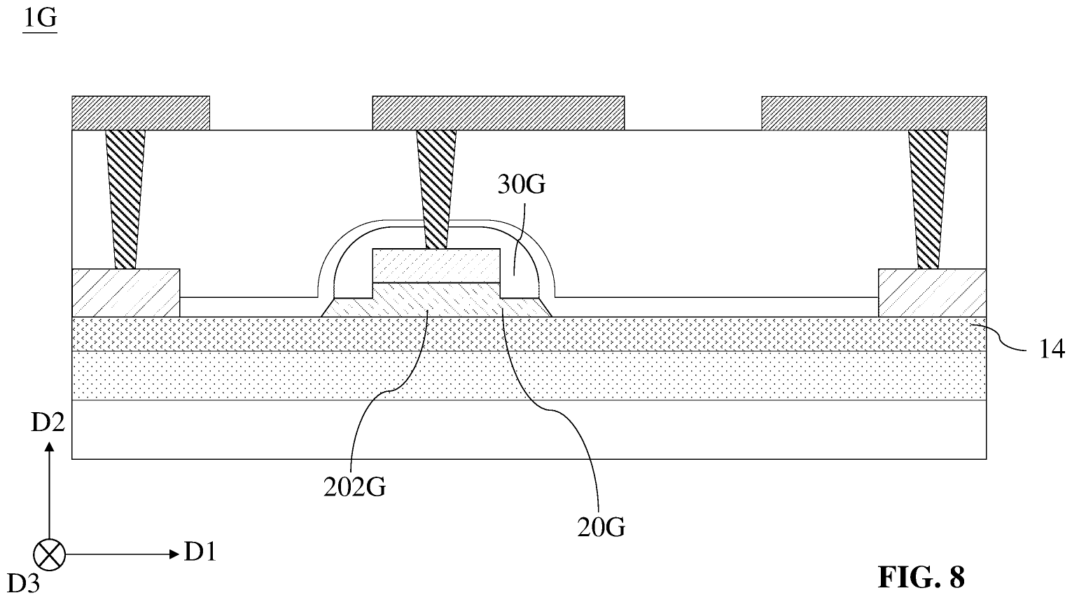

FIG. 8 is a vertical cross-sectional view of a semiconductor device 1G according to some embodiment of the present disclosure. The semiconductor device 1G is similar to the semiconductor device 1A as described and illustrated with reference to FIGS. 1A and 1B, except that the doped nitride-based semiconductor layer 20A is replaced by a doped nitride-based semiconductor layer 20G. The sidewalls of the bottom portion 202G of the doped nitride-based semiconductor layer 20G are oblique with respect to the nitride-based semiconductor layer 14. The sidewalls of the bottom portion 202G are outside of a vertical projection of the protection layer 30G on the nitride-based semiconductor layer 14. The profile of the bottom portion 202G can be achieved by tuning the recipes at a stage that transferring profile to the doped nitride-based semiconductor layer 20G. The profile of the bottom portion 202G can further smooth the variety/change to the 2DEG concentration.

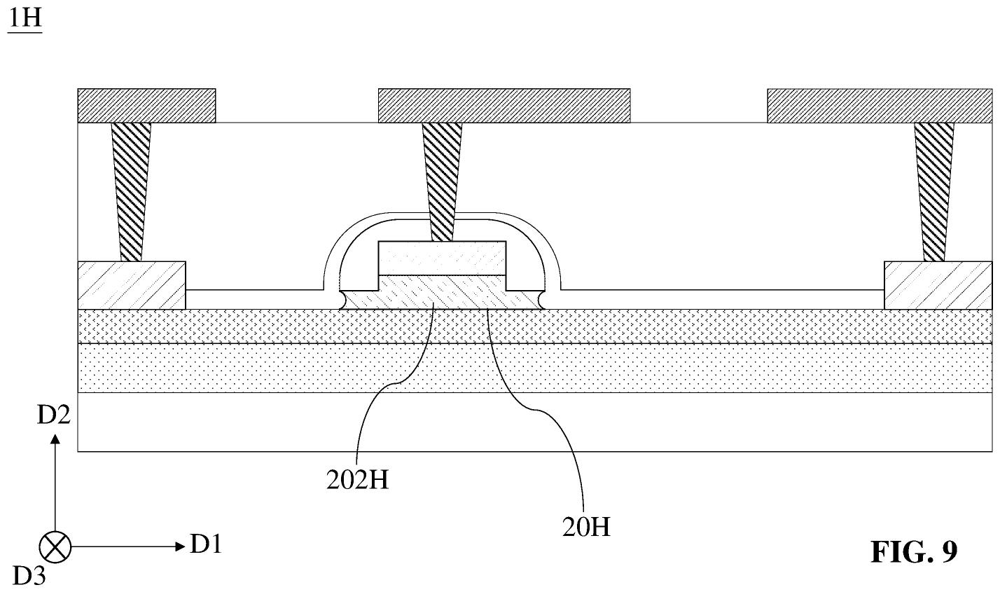

FIG. 9 is a vertical cross-sectional view of a semiconductor device 1H according to some embodiment of the present disclosure. The semiconductor device 1H is similar to the semiconductor device 1A as described and illustrated with reference to FIGS. 1A and 1B, except that the doped nitride-based semiconductor layer 20A is replaced by a doped nitride-based semiconductor layer 20H. The sidewalls of the bottom portion 202H of the doped nitride-based semiconductor layer 20H are curved. The profile of the bottom portion 202H can be achieved by tuning the recipes at a stage that transferring profile to the doped nitride-based semiconductor layer 20H. The profile of the bottom portion 202H can also further smooth the variety/change to the 2DEG concentration.

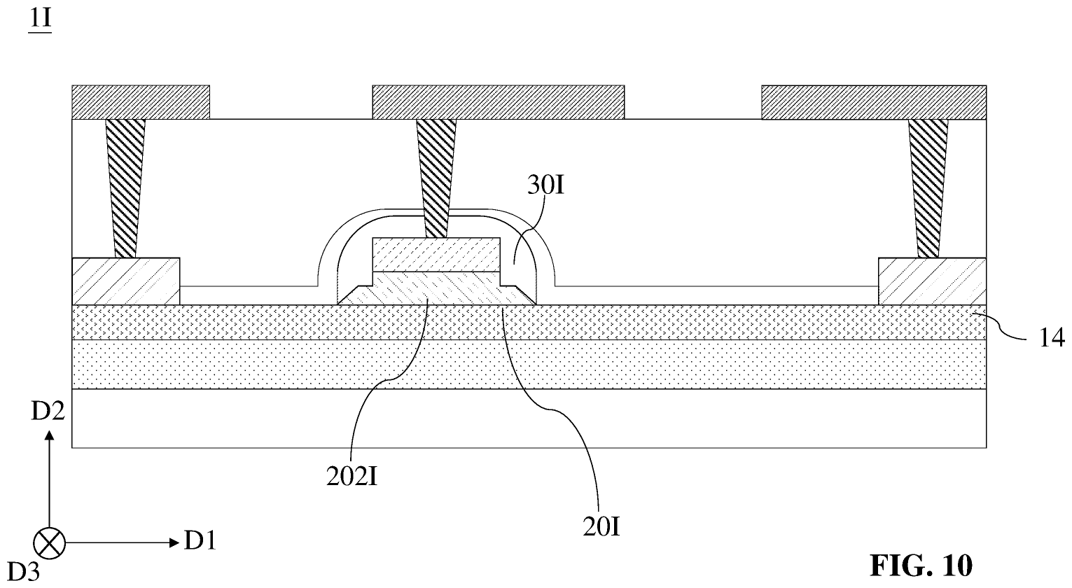

FIG. 10 is a vertical cross-sectional view of a semiconductor device 1I according to some embodiment of the present disclosure. The semiconductor device 1I is similar to the semiconductor device 1A as described and illustrated with reference to FIGS. 1A and 1B, except that the doped nitride-based semiconductor layer 20A is replaced by a doped nitride-based semiconductor layer 20I. The sidewalls of the bottom portion 202I of the doped nitride-based semiconductor layer 20I are oblique with respect to the nitride-based semiconductor layer 14. The sidewalls of the bottom portion 202I of the doped nitride-based semiconductor layer 20I are entirely oblique. No vertical border is made on the sidewalls of the bottom portion 202I of the doped nitride-based semiconductor layer 20I. The sidewalls of the bottom portion 202I are outside of a vertical projection of the protection layer 301 on the nitride-based semiconductor layer 14.

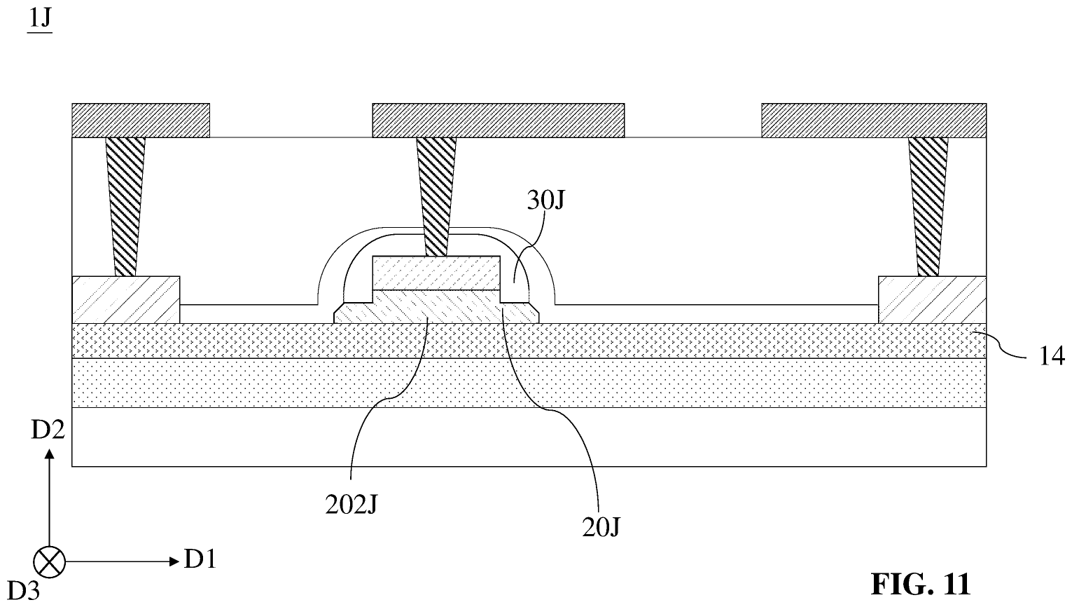

FIG. 11 is a vertical cross-sectional view of a semiconductor device 1J according to some embodiment of the present disclosure. The semiconductor device 1J is similar to the semiconductor device 1A as described and illustrated with reference to FIGS. 1A and 1B, except that the doped nitride-based semiconductor layer 20A is replaced by a doped nitride-based semiconductor layer 20J. The sidewalls of the bottom portion 202J of the doped nitride-based semiconductor layer 20J have corners oblique with respect to the nitride-based semiconductor layer 14. The sidewalls of the bottom portion 202J are outside of a vertical projection of the protection layer 30J on the nitride-based semiconductor layer 14.

In the embodiments of the semiconductor devices 1G, 1H, 1I, and 1J, since the sidewalls of the bottom portions of the doped nitride-based semiconductor layers can be curved or oblique, the modulation to the 2DEG region can be adjusted according to the requirements. For example, with the 2DEG region, on resistant of the device can be turned to become greater or less, which can be applied into low or high voltage devices.

By the above configuration, in embodiments of the present disclosure, the doped nitride-based semiconductor layer is formed to have portions with different thicknesses, such that the 2DEG concentration distribution in the channel layer can be changed, thereby achieving an uniform electrical distribution therein. Furthermore, the aforesaid design of the doped nitride-based semiconductor layer can be applied with a single field plate in the semiconductor device, and thus a better electrical distribution can be achieved with fewer used field plates.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 m of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer;
a doped nitride-based semiconductor layer disposed over the second nitride-based semiconductor layer, wherein the doped nitride-based semiconductor layer has a first portion and a second portion over the first portion and narrower than the first portion;
a gate electrode disposed over the doped nitride-based semiconductor layer and narrower than the first portion; and
a protection layer disposed over the doped nitride-based semiconductor layer and the gate electrode, wherein a top surface of the first portion of the doped nitride-based semiconductor layer is covered by the protection layer, and a sidewall of the first portion of the doped nitride-based semiconductor layer is free from coverage by the protection layer.

2. The semiconductor device of claim 1, wherein the gate electrode has a width substantially the same as a width of the second portion of the doped nitride-based semiconductor layer.

3. The semiconductor device of claim 1, wherein the first portion of the doped nitride-based semiconductor layer has a first extending portion and a second extending portion, wherein the first extending portion is shorter than the second extending portion.

4. The semiconductor device of claim 3, wherein the second extending portion viewed along a direction normal to the second nitride-based semiconductor layer is in a zig zag profile.

5. The semiconductor device of claim 4, wherein the first extending portion viewed along the direction normal to the second nitride-based semiconductor layer is in a rectangular profile.

6. The semiconductor device of claim 3, wherein profiles of the first and second extending portions viewed along a direction normal to the second nitride-based semiconductor layer are asymmetrical.

7. The semiconductor device of claim 3, wherein the first and second extending portions viewed along a direction normal to the second nitride-based semiconductor layer have different areas.

8. The semiconductor device of claim 7, wherein the area of the first extending portion viewed along the direction normal to the second nitride-based semiconductor layer is less than the area of the second extending portion viewed along the direction normal to the second nitride-based semiconductor layer.

9. The semiconductor device of claim 3, wherein the second extending portion viewed along a direction normal to the second nitride-based semiconductor layer has at least one taper profile.

10. The semiconductor device of claim 1 wherein the sidewall of the first portion of the doped nitride-based semiconductor layer is vertical with respect to the second nitride-based semiconductor layer.

11. The semiconductor device of claim 1, wherein the sidewall of the first portion of the doped nitride-based semiconductor layer is oblique with respect to the second nitride-based semiconductor layer.

12. The semiconductor device of claim 1, wherein the sidewall of the first portion of the doped nitride-based semiconductor layer is curved.

13. The semiconductor device of claim 1, wherein the sidewall of the first portion of the doped nitride-based semiconductor layer is outside of a vertical projection of the protection layer on the second nitride-based semiconductor layer.

14. The semiconductor device of claim 1, wherein a first sidewall of the protection layer is closer to the gate electrode than a second sidewall of the protection layer opposite the first sidewall.

15. The semiconductor device of claim 1, wherein the protection layer has a curved top surface.

16. A method for manufacturing a semiconductor device, comprising:
forming a first nitride-based semiconductor layer disposed over a substrate;
forming a second nitride-based semiconductor layer on the first nitride-based semiconductor layer;
forming a doped nitride-based semiconductor layer over the second nitride-based semiconductor layer;
forming a gate electrode on the doped nitride-based semiconductor layer with portions of the doped nitride-based semiconductor layer exposed from the gate electrode;
thinning the exposed portion of the doped nitride-based semiconductor layer;
forming a protection layer covering the doped nitride-based semiconductor layer and the gate electrode;
removing portions of the protection layer to expose the doped nitride-based semiconductor layer; and
removing the portions of the doped nitride-based semiconductor layer which are exposed from the protection layer.

17. The method of claim 16, further comprising:
forming a dielectric layer covering the protection layer.

18. The method of claim 16, wherein thinning the exposed portion of the doped nitride-based semiconductor layer is performed by using an etching process.

19. The method of claim 18, wherein the gate electrode serves as a mask during the etching process.

20. The method of claim 16, further comprising:
patterning the protection layer into a profile, wherein removing the portions of the doped nitride-based semiconductor layer is performed such that the profile is transferred to the doped nitride-based semiconductor layer.

21-25. (canceled)
